(19) United States
(12) Patent Application Publication
(10) Pub. No.: US 2004/0258119 A1
(43) Pub. Date: Dec. 23, 2004

(54) Method and apparatus for suppression of spatial-hole burning in second of higher order DFB lasers

(75) Inventors: Ali M. Shams-Zadeh-Amiri, North York (CA); Wei Li, Waterloo (CA); Tom Haslett, Toronto (CA); Seyed Mostafa Sadeghi, Toronto (CA)

Correspondence Address: HOFFMANN & BARON, LLP, 6900 JERICHO TURNPIKE, SYOSSET, NY, 11791, US

(73) Assignee: Photonami Inc.

(21) Appl. No.: 10/863,988

(22) Filed: Jun. 9, 2004

Related U.S. Application Data
(60) Provisional application No. 60/477,262, filed on Jun. 10, 2003.

(51) Int. Cl. H01S 3/08; H01S 5/00

(52) U.S. Cl. 372/45

(57) ABSTRACT

A surface emitting semiconductor laser is shown having a semiconductor laser structure defining an intrinsic cavity having an active layer, opposed cladding layers contiguous to said active layer, a substrate and electrodes by which current can be injected into said semiconductor laser structure to cause said laser structure to emit an output signal in the form of at least a surface emission. The intrinsic cavity is configured to have a dominant mode on a longer wavelength side of a stop band. A structure such as a buried heterostructure for laterally confining an optical mode is included. A second order distributed diffraction grating is associated with the intrinsic cavity, the diffraction grating having a plurality of grating elements having periodically alternating optical properties when said current is injected into said laser structure. The grating is sized and shaped to generate counter-running guided modes within the intrinsic cavity wherein the grating has a duty cycle of greater than 50% and less than 90%. Also provided is a means for shifting a phase of said counter-running guided modes within the cavity to alter a mode profile to increase a near field intensity of said output signal.

### FIELD OF THE INVENTION

This invention relates generally to the field of telecommunications and in particular to optical signal based telecommunication systems. Most particularly, this invention relates to lasers, such as semiconductor diode lasers, for generating pump and carrier signals for such optical telecommunication systems.

### BACKGROUND OF THE INVENTION

A number of different laser sources are currently available as optical signal sources for telecommunications. These include various forms of fixed, switchable or tunable wavelength lasers, such as Fabry-Perot, Distributed Bragg Reflector (DBR), Vertical Cavity Surface Emitting Lasers (VCSEL) and Distributed Feedback (DFB) designs. Currently the most common form of signal carrier source used in telecommunication applications are edge emitting index coupled DFB laser sources, which have good performance in terms of modulation speed, output power, stability, noise and side mode suppression ratio (SMSR). In this sense SMSR refers to the property of DFB lasers to have two low threshold longitudinal modes having different wavelengths at which lasing can occur, of which one is typically desired and the other is not. SMSR comprises a measure of the degree to which the undesired mode is suppressed, thus causing more power to be diverted into the preferred mode, while also having the effect of reducing cross-talk from the undesired mode emitting power at the wavelength of another DWDM channel. In addition, by selecting an appropriate semiconductor material and laser design, communication wavelengths can be readily produced.

However, there are also many drawbacks to edge emitting lasers as signal sources. The major issue is the bulk and cost of packaging the laser due to the requirement in most cases of including an optical isolator and expensive aspheric lenses to couple the light into a single mode fiber. In addition, edge emitting lasers can only be properly tested once the wafer has been cleaved into bars and the edges anti-reflection coated. These steps are time consuming and result in yield loss and are therefore expensive. All this has lead to a search for a signal source that is simpler, has a higher manufacturing yield, is less expensive to package and is therefore much less expensive overall. At the same time, the desired source must achieve acceptable similar or better output characteristics. One possible solution is a surface emitting DFB laser structure.

A surface-emitting DFB laser suitable for use as a communications signal source consists of an active gain layer sandwiched between optical confinement layers having a lateral optical confinement structure such that there is a single transverse mode. In addition, there is a distributed feedback grating of second or higher order somewhere within the optical mode volume. While the use of higher ordered gratings can be considered, in the rest of this document reference will be made primarily to second order gratings as it represents the best example and performance. Not all higher order gratings can demonstrate the same performance characteristics as a second order grating. Originally, the use of a second-order index grating in edge-emitting DFB lasers was proposed to lift the degeneracy problem of the spectrum of a symmetric first order DFB laser. In DFB lasers, the two counter-propagating modes can interfere constructively and destructively to produce two primary potential lasing modes at the edges of the stop band. The stop band is defined as the region between these two primary modes where no other lasing modes can occur. In a first order structure, these two modes have equal modal gain and are therefore equally likely to lase (assuming the laser is symmetric at the ends of the cavity). For a second order structure, these two modes experience different radiation loss and therefore there is now a net gain discrimination mechanism at play. The mode with destructive interference of optical amplitudes within the cavity has less radiation loss and hence a lower threshold gain in comparison with the second mode.

This approach for avoiding the degeneracy problem in symmetric first-order DFB lasers is preferable to the more usual method, which is done by breaking the symmetry of the laser by anti-reflection (AR) coating one facet and high-reflection (HR) coating the other. This is because wavelength control is difficult using the usual approach since the reflection from the HR coated facet can shift the wavelength appreciably, thus making wavelength yield an important issue even though SMSR yield improves.

There are other methods for improving single-mode yield by lifting the degeneracy. Quarter-wave phase shifted gratings are probably the most common alternative to mixed AR/HR facet coatings, where the phase shift allows a single mode in the middle of the stop band (at or very close to the Bragg wavelength) that has a lower threshold gain than the two modes at the edges of the stop band and is therefore the preferred lasing mode. Another less common method is employing complex coupled gratings. The term complex coupled grating refers to the situation where the coupling coefficient of the DFB laser is a complex number. This can be achieved by so-called active coupling (gain or loss corrugation) and/or by using a second or higher order grating in which coupling to the radiation field is responsible for the imaginary part of the coupling coefficient. Each method has its own advantages and disadvantages.

The radiation loss mode selection mechanism in second-order DFB lasers described above favors a lasing mode having a poor surface-emitting near-field profile for coupling into single mode fibers. The favored mode, which by definition has less radiation loss, also emits correspondingly less power from the surface. Therefore, simply using a second-order index coupled grating DFB laser is not sufficient to make a surface-emitting laser suitable for optical communications applications. To improve the shape of the laser beam while removing radiation loss as a mode selection mechanism, the use of a quarter-wave phase shift region in a second order grating was proposed by Kinoshita [J.-I. Kinoshita, “Axial profile of grating-coupled radiation from second-order DFB lasers with phase shifts” IEEE Journal of Quantum Electronics, vol. 26, pp. 407-412, March 1990]. As will be described later, this solution is not complete in its understanding or solution of the overall problem of surface-emitting DFB lasers.

Outside of the telecommunications field, an example of a surface emitting DFB laser structure is found in U.S. Pat. No. 5,727,013. This patent teaches a single lobed surface emitting DFB laser for producing blue/green light where the second order grating is written in an absorbing layer within the structure or directly in the gain layer to alter the laser beam. While interesting, this patent does not disclose how the grating affects fibre-coupling efficiency (since it is not concerned with any telecom applications). This patent also fails to teach what parameters control the balance between total output power and fibre coupling efficiency or how to effectively control the mode. Lastly, this patent fails to teach a surface emitting laser that is suitable for telecommunication wavelength ranges.

Without doubt a key concern that is always associated with quarter-wave phase shifted DFB laser designs is that of spatial hole burning. Spatial hole burning is a non-linear effect that results from a highly non-uniform optical field within the laser cavity. At high injection rates, areas where the optical field is most intense become saturated more quickly and therefore carrier concentrations in these areas become depleted relative to other areas in the laser cavity. Due to the plasma effect, this local carrier depletion in turn leads to a local refractive index change. The local refractive index change leads to non-linear effects that degrade the performance of the laser. The most obvious symptom is a decrease in the SMSR as secondary modes are enhanced by the effect relative to the main mode. In more extreme operating conditions, mode hopping can occur.

Spatial hole burning comes into play differently for edge emitting and surface emitting lasers employing second-order gratings. In an edge emitting laser, the coupling coefficient is kept relatively low by design, otherwise the efficiency of emission from the edge is low. The low coupling coefficient in turn helps alleviate hole burning because the optical field intensity remains fairly uniform throughout the cavity. In contrast, for a surface emitting laser, what is desired is a concentrated single-lobed optical field to achieve optimal coupling to a single mode fiber. While achievable through different designs, the simplest is to incorporate a quarter-wave phase shift. Optimal theoretical performance also calls for a high coupling coefficient to improve the surface emission efficiency and more tightly concentrate the field over the phase shift. By so highly concentrating the optical field in one place, the optimal surface-emitting design is thus simultaneously the worst case design for spatial hole burning. Thus early on in the research of surface-emitting DFB lasers this inherent conflict between the requirements for maximizing the optical field concentration from the surface for coupling and intensity purposes and minimizing the concentration for hole-burning reasons was realized. From the above consideration it can be seen that the control of spatial hole burning is of paramount importance in the design of surface emitting DFB lasers employing a quarter-wave phase shift for the control of the optical mode and field profile.

Two patents attempting to mitigate these hole burning effects are U.S. Pat. No. 4,958,357 and U.S. Pat. No. 5,970,081. In the first, complicated electrode geometries are envisioned to allow stronger current injection into regions susceptible to hole burning. This solution is at best partial in terms of performance and involve greater complication in both fabrication and deployment, leading to higher costs. Furthermore, the patent is based on an index-coupled grating and does not teach that other factors can have a significant effect in mitigating the hole burning effects. In the second, which is also based on index-coupled gratings, hole burning is mitigated by distributing the phase shift over a larger region (defined as greater than one grating period) to decrease the peak optical field intensity. This method, while viable, produces less than optimal field profiles and again requires a more complicated fabrication procedure. Again there is no teaching of other mitigating factors. In both patents, the failure to recognize and understand other critical mitigating factors leads to inconsistent, costly and unacceptable results. The teachings of these patents are therefore not commercially viable.

As far as single-mode operation is concerned, there is no point in making a quarter-wave phase shifted laser with complex gratings. The quarter-wave phase shift on its own is sufficient to control the mode appropriately. However, in order to improve the FM response of a DFB laser, Okai first proposed the idea of using a first-order complex coupled grating in a quarter-wave phase shifted DFB laser [M. Okai, M. Suzuki, and M. Aoki, “Complex-Coupled λ/4-shifted DFB lasers with a flat FM response,” IEEE Journal of Selected Topics in Quantum Electronics. Vol. 1, pp. 461-465, June 1995]. An in-phase complex grating is one in which the real and imaginary terms in the coupling coefficient are the same sign and is normally embodied as a gain-coupled grating. It follows that an anti-phase complex grating is one in which the signs are opposite, the most common example being a loss-coupled grating. In addition to improving the FM response as desired, Okai also noted that in-phase first order complex gratings can suppress spatial hole burning while anti-phase complex gratings intensify hole burning and deteriorate the laser performance.

What is desired is a surface emitting laser structure, which can provide useful amounts of output power without the detrimental spatial hole burning problems or complicated and partial solutions associated with the prior art phase shifted designs. What is also desired is a structure which has low chirp and is insensitive to back-reflection.

### SUMMARY OF THE INVENTION

The present invention relates to the theory and physics of suppression of the spatial hole burning effect in a first order quarter-wave phase shifted DFB laser. With a proper understanding of the physics, it is shown that a gain-coupled, second order, quarter-wave phase shifted grating with appropriate duty cycle constitutes a surface emitting laser having excellent optical mode and spectral properties while at the same time being virtually impervious to spatial hole burning. A laser design according to the present invention eliminates the necessity for the myriad ways, generally complicated, designed to alleviate hole burning. Experimental results from gain-coupled, phase shifted, second order grating lasers according to the present invention are also provided which demonstrate the performance of the present invention.

An aspect of the present invention is to show that without using complicated multi-electrode injection techniques or difficult phase-shifting methods, it is possible to greatly reduce the occurrence of hole-burning-induced multimode operation of a second-order DFB laser having a quarter-wave phase shift region through judicious choice of the duty cycle. This possibility arises from the fact that a second-order grating is a complex coupled grating by nature and with a complex coupled grating it is possible to strongly reduce spatial hole burning effects.

Quarter-wave phase shift, second order gratings have been proposed in the past but with very few demonstrated results. To date, duty cycle of the grating, defined as the ratio of the grating tooth width to the grating period, has not been considered as an important design parameter. According to the present invention this is because until now there has been a failure to fully recognize and understand the design factors which directly affect spatial hole burning. According to the present invention, within a particular range of duty cycles, the detrimental effect of spatial hole burning—which limits the operating current of the laser and therefore the output power—is naturally mitigated by making appropriate design choices. Further, according to the present invention this effect can be additively combined with a gain coupled grating design such that the laser is virtually impervious to hole burning. Therefore a laser design according to the present invention has the advantages of a quarter-wave phase shift (namely good single mode operation and good surface-emitting optical mode shape for fiber coupling) without incurring the typical detrimental effects due to spatial hole burning, such as mode-hopping. At the same time, the design has inherently low chirp and is highly insensitive to back-reflected light.

In one aspect of the present invention it is demonstrated that since a second-order grating is inherently a complex grating, it is possible to reduce or avoid spatial hole burning by judicious choice of the duty cycle of the grating. Therefore even an index-coupled design can show improved resistance to spatial hole burning if the duty cycle of a second order grating is chosen properly. Furthermore, this improvement through careful selection of duty cycle can have an additive effect when used with a gain-coupled grating to attain extreme insensitivity to spatial hole burning. Conversely, according to the present invention quarter-wave phase shifted loss-coupled gratings are particularly poor performers as the intensified spatial hole burning inherent to loss-coupled designs is made even worse because of the duty cycles necessary to achieve a useful optical field distribution.

It is an object of the present invention to provide a surface emitting laser structure which is both suitable for telecommunications applications and which avoids or minimizes spatial hole burning problems associated with the prior art designs. An object of the present invention is to provide a low-cost optical signal source that is capable of generating signals suitable for use in the optical broadband telecommunications signal range. Most preferably such a signal source would be in the form of a surface emitting semiconductor laser which can be fabricated using conventional semiconductor manufacturing techniques and yet which would have higher yields than current techniques. Thus it is an object of the present invention to produce signal sources at a lower cost than as compared to the prior art techniques referred to above.

It is a further object of the present invention that such a signal source would have enough power, wavelength stability and precision for broadband communications applications without encountering impractical limits due to spatial hole burning. More particularly what is needed is a laser structure where the mode shape is optimised to permit fibre coupling and yet which can be made using conventional lithographic and materials techniques in the semiconductor art. Thus what is desired is a surface emitting laser which includes a means to ameliorate spatial hole burning to permit practical values of output power to arise from the laser. Further such a device would display minimal chirp to permit signal transportation and manipulation without unacceptable pulse broadening. Still further, the device would exhibit an insensitivity to back-reflected light, allowing the device to be operated as a communications signal source without the need for the inclusion of an optical isolator to maintain stable performance.

What is also desired is a semiconductor laser signal source having a signal output that is easily and efficiently coupled to a single mode optical fibre. Such a device would also preferably be fabricated as an array on a single wafer-based structure and may be integrally and simultaneously formed or fabricated with adjacent structures such as signal absorbing adjoining regions and photodetector devices.

A further feature of the present invention relates to efficiencies in manufacturing. The larger the number of arrayed signal sources the greater the need for a low fault rate fabrication. Thus, for example, a forty source array fabricated at a yield of 98% per source will produce an array fabrication yield of only 45%. Thus, improved fabrication yields are important to cost efficient array fabrication.

A further aspect of the invention is that each laser source of the array can be fabricated to operate at the same or to different wavelengths and most preferably to wavelengths within the telecommunications signal bands. Further, such a device could have a built in detector that, in conjunction with an external feedback circuit, could be used for signal monitoring and maintenance.

### BRIEF DESCRIPTION OF THE DRAWINGS

Reference will now be made, by way of example only, to preferred embodiments of the present invention by reference to the attached figures, in which:

FIG. 1 is a side view of one embodiment of a surface emitting semiconductor laser according to the present invention having a quarter-wave phase shifted second order grating formed in a gain medium;

FIG. 2 is an end view of the embodiment of FIG. 1;

FIG. 3 is a plot mode spectra from various lasing structures;

FIG. 4a is a plot of mode spectra for duty cycle of greater than 50%;

FIG. 4b is a plot of mode spectra for duty cycle of less than 50%;

FIG. 5 is a plot of a mode spectrum for an index-coupled grating where κL=2;

FIG. 6 is a plot of a mode spectrum for a gain-coupled grating where κL=2;

FIG. 7 is a plot of a mode spectrum for a loss-coupled grating where κL=2;

FIG. 8 is a plot of a mode spectrum for an index-coupled grating where κL=3;

FIG. 9 is a plot of a mode spectrum for a loss-coupled grating where κL=3;

FIG. 10 is a plot of a mode spectrum for a gain-coupled grating where κL=3;

FIG. 11 is a plot of a mode spectrum for an index-coupled grating where κL=4.

FIG. 12 is a plot of a mode spectrum for a grain-coupled grating where κL=4.

FIG. 13 is a plot of power versus injection current for a laser according to the present invention;

FIG. 14 is a plot of a spectrum for a laser according to the present invention for a current just above threshold current; and

FIG. 15 is a plot of a spectrum for a laser according to the present invention for a current far above threshold current.

### DETAILED DESCRIPTION OF THE PREFERRED EMBODIMENTS

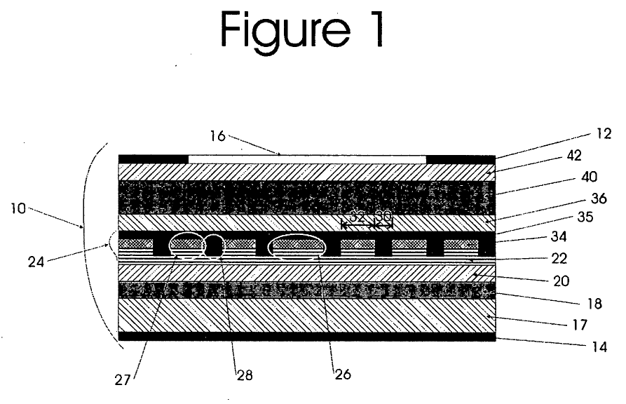

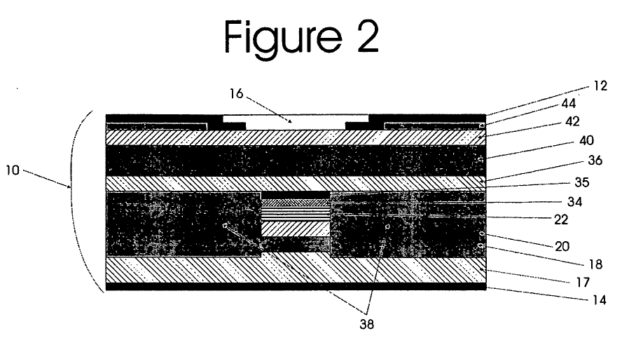

FIG. 1 is a side view of one embodiment of a surface emitting semiconductor laser structure 10 according to the present invention, while FIG. 2 is an end view of the same structure. The laser structure 10 is comprised of a number of layers built up one upon the other using, for example, standard semiconductor fabrication techniques. It will be appreciated that the use of such known semiconductor fabrication techniques for the present invention means that the present invention may be fabricated efficiently in large numbers without any new manufacturing techniques being required.

In this disclosure the following terms shall have the following meanings. A p-region of a semiconductor is a region doped with electron acceptors in which holes (vacancies in the valence band) are the dominant current carriers. An n-region is a region of a semiconductor doped so that it has an excess of electrons as current carriers. An output signal means any optical signal which is produced by the semiconductor laser of the present invention. The mode volume means the volume in which the bulk of the optical mode exists, namely, where there is significant light (signal) intensity. For example, the mode volume could be taken as the boundary enclosing 80% of the optical mode energy. For the purposes of this disclosure, a distributed diffraction grating is one in which the grating is associated with the active gain length or absorbing length of the lasing cavity so that feedback from the grating causes interference effects that allow oscillation or lasing only at certain wavelengths, which the interference reinforces.

The diffraction grating of the present invention is comprised of grating or grid elements, which create alternating optical properties, most preferably alternating gain and/or refractive index effects. Two adjacent grating elements define a grating period. The alternating gain effects are such that a difference in gain arises in respect of the adjacent grating elements with one being a relatively high gain effect and the next one being a relatively low gain effect. The present invention comprehends that the relatively low gain effect may be a small but positive gain value or may be no actual gain. Thus, the present invention comprehends any absolute values of gain effect in respect of the grating elements, provided the relative difference in gain effect and index is enough between the adjacent grating elements to set up the interference effects of lasing at only certain wavelengths. The present invention comprehends any form of grating that can establish the alternating gain effects described above, including gain coupled gratings in the active region.

The overall effect of a diffraction grating according to the present invention may be defined as being to limit laser oscillation to one of two longitudinal modes which may be referred to as a single-mode output signal. According to the present invention various techniques are employed to further design the laser such that the mode profile is capable of being effectively coupled to a fibre.

As shown in FIG. 1, the two outside layers 12 and 14 of the laser structure 10 are electrodes. The purpose of the electrodes is to be able to inject current into the laser structure 10. It will be noted that electrode 12 includes an opening 16. The opening 16 permits the optical output signal to pass outward from the laser structure 10, as described in more detail below. Although an opening is shown, the present invention comprehends the use of a continuous electrode, providing the same is made transparent, at least in part, so as to permit the signal generated to pass out of the laser structure 10. Simple metal electrodes, having an opening 16, have been found to provide reasonable results and are preferred due to ease of fabrication and low cost. The window opening for the light output can be situated in the electrode 14 (n-side opening). In the latter case, it is also comprehended that removal of part of the substrate is conceivable within the spirit of this invention to allow for better access to the optical output.

Adjacent to the electrode 14 is an n+ InP substrate, or wafer 17. Adjacent to the substrate 17 is a buffer layer 18 which is preferably comprised of n-InP. The next layer is a confinement layer 20 formed from n-InGaAsP. The generic composition of this and other quaternary layers is of the form InₓGa₁₋ₓAs_{y}P_{1-y} while ternary layers have the generic composition In₁₋ₓGaₓAs. The next layer is an active layer 22 made up of alternating thin layers of active quantum wells and barriers, both comprised of InGaAsP or InGaAs. As will be appreciated by those skilled in the art InGaAsP or InGaAs is a preferred semiconductor because these semiconductors, within certain ranges of composition, are capable of exhibiting optical gain at wavelengths in the range of 1200 nm to 1700 nm or higher, which comprehends the broadband optical spectra of the 1300 nm band (1270-1320 nm), the S-band (1470-1530 nm), the C-band (1525 nm to 1565 nm), and the L-band (1568 to 1610 nm). Other semiconductor materials, for example GaInNAs, InGaAlAs are also comprehended by the present invention, provided the output signal generated falls within the broadband range. Another relevant wavelength range of telecommunications importance for which devices following this invention could be designed using appropriate material compositions (for example InGaAs/GaAs) is the region from 910 to 990 nm, which corresponds to the most commonly encountered wavelength range for pumping optical amplifiers and fiber lasers based on Er, Yb or Yb/Er doped materials.

The next layer above the active layer 22 is a p-InGaAsP confinement layer 34.

In the embodiment of FIG. 1, a diffraction grating 24 is formed in the active layer 22 and confinement layer 34. The grating 24 is comprised of alternating high gain portions 27 and low gain portions 28. Most preferably, the grating 24 is a regular grating, namely has a constant period across the grating, and is sized, shaped and positioned in the laser 10 to comprise a distributed diffraction grating as explained above. In this case, the period of the grating 24 is defined by the sum of a length 32 of one high gain portion 27 and a length 30 of the adjacent low gain portion 28. The low gain portion 28 exhibits low or no gain as compared to the high gain portion 27 as in this region most or all of the active structure has been removed. According to the present invention, the grating 24 is a second order grating, namely, a grating having a period equal to the guide wavelength within the cavity which results in output signals in the form of surface emission.

Located centrally in the grating 24 is a means for phase shifting, which comprises a slightly wider high gain “tooth” 26. This tooth 26 is sized and shaped to deliver a phase shift of one quarter of a wavelength. The present invention comprehends other forms of phase shift elements as will be understood by those skilled in the art. What is needed is to provide enough of a phase shift to the grating to alter the near field intensity profile to change the dominant mode from a dual peaked configuration to a single peaked configuration where the peak is generally located over the phase shift. Such a mode profile can be more efficiently coupled to a single-mode fibre than the dual lobed profile. Thus provided that the mode profile is altered to improve coupling efficiency, the amount of the phase shift, and the manner of affecting the phase shift can be varied without departing from the spirit of the present invention.

For example, multiple phase shifts may be employed yielding an overall quarter wave shift, e.g. two λ/8, or two 3 λ/8 or other combinations are comprehended. As well a continuously chirped grating or a modulated pitch grating are also comprehended although these are more difficult to fabricate. Tapering the effective index of the waveguide is another way to distribute the phase shift within the cavity. It is important to note that while other methods of phase shift can be employed, they must be designed carefully to be consistent with having the dominant mode of the intrinsic cavity remain at the longer wavelength side of the stop band and to maintain a desirable mode shape in the longitudinal axis.

The next layer above the active layer 22 and confinement layer 34 is a layer of InP to bury and in-fill the grating 35. Located above the grating burying layer 35 is a p-InP buffer region 36. Located above layer 36 is a p-InP cladding layer 40, which is in turn surmounted by a p⁺⁺-InGaAs cap layer 42.

It will be understood by those skilled in the art that a semiconductor laser built with the layers configured as described above can be tuned to produce an output signal of a predetermined wavelength as the distributed feedback from the diffraction grating written in the active layer renders the laser a single mode laser. The precise wavelength of the output signal will be a function of a number of variables, which are in turn interrelated and related to other variables of the laser structure in a complex way. For example, some of the variables affecting the output signal wavelength include the period of the grating, the index of refraction of the active, confinement, and cladding layers (some of which in turn typically change with temperature as well as injection current), the composition of the active regions (which affects the layer strain, gain wavelength, and index), and the thickness of the various layers that are described above. Another important variable is the amount of current injected into the structure through the electrodes. Thus, according to the present invention by manipulating these variables a laser structure can be built which has an output with a predetermined and highly specific output wavelength. Such a laser is useful in the communications industry where signal sources for the individual channels or signal components which make up the DWDM spectrum are desired. Thus the present invention comprehends various combinations of layer thickness, gain period, injection current and the like, which in combination yield an output signal having a power, wavelength and bandwidth suitable for telecommunications applications.

However, merely obtaining the desired wavelength and bandwidth is not enough. A more difficult problem solved by the present invention is to produce the specific wavelength desired from a second order grating (and thus, as a surface emission) in such a manner that it can be controlled for efficient coupling, for example, to an optical fibre. The spatial characteristics of the output signal have a big effect on the coupling efficiency, with the ideal shape being a single mode, single-lobed Gaussian. For surface emitting semiconductor lasers the two primary modes include a divergent dual-lobed mode, and a single-lobed mode. The former is very difficult to couple to a single mode fibre as is necessary for most telecommunications applications because the fibre has a single Gaussian mode.

The term duty cycle means the fraction of the length of one grating period that exhibits high gain as compared to the grating period. In more simple terms, the duty cycle may be defined as the portion of the period of the grating 24 that exhibits high gain. This parameter of duty cycle is controlled in gain coupled lasers, such as illustrated in FIG. 1, by etching away portions of the active layers, with the remaining active layer portion being the duty cycle.

In FIG. 1, it can now be understood that the second order distributed diffraction grating is written by etching the gain medium to form the grating 24. Only one mode (the mode with the lowest gain threshold) will lase, resulting in good SMSR. The present invention comprehends that the desired lasing mode is single lobed and approximates a Gaussian profile. In this way the lasing mode can be more easily coupled to a fibre, since the profile of the power or signal intensity facilitates coupling the output signal to a fibre. The phase shifted second order active-coupled grating has three modes that can lase, with two modes having a higher gain threshold and less coupling efficiency to a single mode fiber in comparison with the dominant mode which is a single lobed mode and having the lowest gain threshold. The dominant mode has a peak at the position of the phase shift, which according to the present invention is placed at the midpoint of the laser structure for optimal coupling into a fibre.

Turning to FIG. 2, a side-view of the laser structure of FIG. 1 is shown. As can be seen in FIG. 2, the electrodes 12 and 14 permit the application of a voltage across the semiconductor laser structure 10 to encourage lasing as described above. Further, it can be seen that the buried heterostructure formed by the waveguide encapsulated by blocking layers 38 serves to confine the optical mode laterally to within the region through which current is being injected. A dielectric layer 44 is provided between the electrode 12 and the cap layer 42 except for a small region above the buried heterostructure. This dielectric layer configuration limits current injection to positions close to the buried heterostructure in a known manner. While a buried heterostructure is shown in this embodiment it is comprehended that a similar structure could be fabricated using a ridge waveguide design to confine the carriers and optical field laterally.

Spatial Hole Burning in First Order Quarter-Wave Phase Shifted Gratings

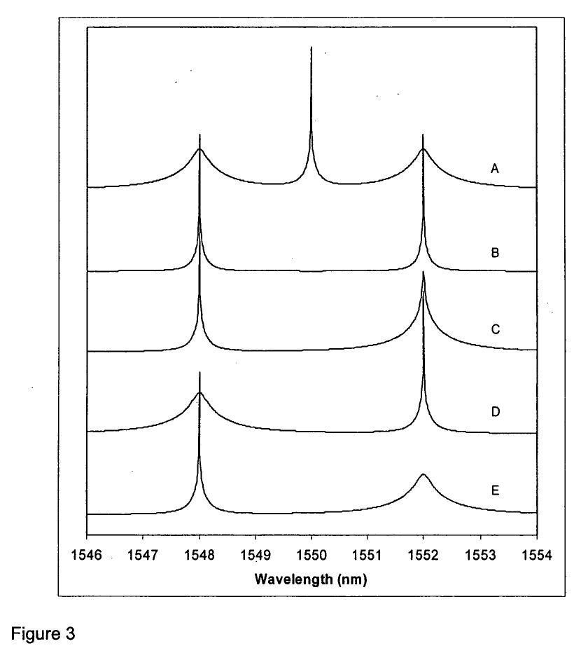

Understanding the role of duty cycle in suppression of spatial hole burning in a quarter-wave phase shifted gain grating can be related to the theory and physics of suppression of spatial hole burning effect in a first order quarter-wave phase shifted DFB laser using a complex grating. In such DFB laser structures, the optical field is strongly peaked in the centre of the cavity over the phase shift. Therefore, in this region the rate of stimulated emission (i.e. stimulated carrier recombination) is highest. Increasing the injection current, and hence stimulating more emission, depletes the carriers at the center of the cavity in the high field region. Due to the plasma effect (where the refractive index increases with a decrease in carrier density) the refractive index in the high field region increases, making the refractive index within the cavity highly non-uniform. This refractive index change modifies the phase of the optical field (effectively making the central quarter-wave phase shift larger) such that the mode at the shorter wavelength side of the stop band competes with the main mode at the center of the stop band. The main mode and the two dominant side modes of a quarter-wave phase-shifted laser are shown in FIG. 3 by trace A. In FIG. 3, in addition to the mode spectrum of a quarter-wave phase shifted grating shown at A there is an intrinsic mode spectra of a symmetric index-coupled grating at B, a symmetric index-coupled grating with spatial hole burning effects included at C, a symmetric in-phase (gain-coupled) grating at D, and a symmetric anti-phase (loss-coupled) grating at E. Note that no phase shift region is incorporated in DFB lasers with the spectra shown in FIGS. 3B-E.

To design the cavity with a quarter-wave phase shift in such a way as to suppress the spatial hole burning effect, it is useful to define the concept of an intrinsic cavity. By intrinsic cavity we mean a cavity obtained by removing the quarter-wave phase shift from the grating. The mode spectrum of the intrinsic cavity plays an important role in the corresponding quarter-wave phase shifted laser. To reduce the spatial hole burning in a quarter-wave phase shifted DFB laser, the dominant mode of the corresponding intrinsic cavity should be on the side of the stop band such that make a balance with the mode competing with the main mode due to the spatial hole burning. In other words, the dominant mode of the corresponding intrinsic cavity should be on the longer wavelength side of the stop band for practical cases of interest. This mode then suppresses the mode on the shorter wavelength side and does not allow it to compete with the main mode at the center of the stop band. It should be noted that in conventional quarter-wave phase shift DFB laser with first-order index grating the mode at the shorter wavelength side of the stop band competes with the main mode. FIG. 3 compares the mode spectra for first order index-coupled gratings with and without spatial hole burning considered, in-phase active gratings, and anti-phase active gratings. From the figure, it is clear that in-phase (gain coupled) gratings suppress the spatial hole burning effect, if they are used in a quarter-wave phase shifted architecture. Conversely, anti-phase (loss-coupled) and index-coupled gratings in a quarter-wave phase shifted design intensify the spatial hole burning effect since the dominant mode of the intrinsic cavity is located at the shorter wavelength side of the stop band, thus deteriorating the corresponding quarter-wave phase shifted laser performance.

Based on the above physical picture of suppression/enhancement of spatial hole burning in first order quarter-wave phase shifted lasers, the present invention comprehends the following results.

(1) In a quarter-wave phase shifted DFB laser with first-order index grating, neither a suppression nor an enhancement mechanism of spatial hole burning is expected.

(2) In a quarter-wave phase shifted DFB laser with a first order gain-coupled grating, the corresponding intrinsic cavity supports the mode at the longer side of the stop band. Therefore, there will be some suppression of spatial hole burning in the corresponding quarter-wave phase shifted grating.

(3) In a quarter-wave phase shifted DFB laser with first-order loss grating, the corresponding intrinsic cavity supports the mode at the shorter side of the stop band. Therefore, there will be an intensifying of spatial hole burning and hence deteriorating performance of the corresponding quarter-wave phase shifted grating.

Suppression of Spatial Hole Burning Effects in Second Order Gratings

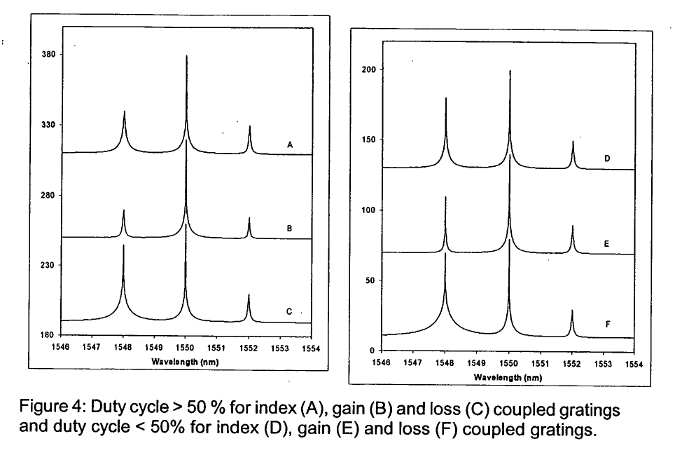

We can now consider the implementation of second order gratings. The effects described below can in principle be applied to certain higher order gratings, but for practical and descriptive reasons we restrict the discussion to second order gratings. The second order grating introduces radiative field (and therefore surface emission) as well as complex coupling coefficient, which can be applied to the hole burning issue. In an important development, we show here that the duty cycle of a second order grating can be used as a means of controlling spatial hole burning. As described in the introduction, we must recognize the second order grating as a complex coupled structure. When taking this novel approach, we consider the effect of the duty cycle of the grating on spatial hole burning, where duty cycle is defined as the ratio of the grating tooth width to the grating period. Using the method first described above of considering the intrinsic cavity, we can calculate mode spectra as shown in FIG. 4 for a second order, quarter-wave phase shifted index-, gain-, and loss-coupled gratings for the cases of duty cycles greater than and less than 50%. Thus, FIG. 4 shows mode spectra as follows: For a duty cycle >50% for index (A), gain (B) and loss (C) coupled gratings and for a duty cycle <50% for index (D), gain (E) and loss (F) coupled gratings.

From FIG. 4, we see that in a quarter-wave phase shifted DFB laser with second-order grating with a duty cycle less than 50%, the intrinsic cavity has a dominant mode at the shorter wavelength side of the stop band and hence the corresponding quarter-wave phase shifted laser suffers from intensified spatial hole burning. This is true, to a greater or lesser extent, for all 3 types (index, gain and loss) of coupling. On the other hand, for a duty cycle greater than 50%, the dominant mode of the intrinsic cavity, except possibly for the loss grating, will be at longer wavelength side of the stop band and hence will result in suppression of spatial hole burning in the corresponding quarter-wave phase shifted laser.

In a quarter-wave phase shifted DFB laser with a second-order gain-coupled grating, for duty cycles less than 50% the laser cavity may not have sufficient gain to lase at room temperature. Even at high levels of gain or with a longer cavity, the coupling coefficient due to the gain perturbation and the coupling coefficient due to the radiation field tend to cancel each other and the grating may even become anti-phase, which is harmful as far as spatial hole burning is concerned. To avoid a high material gain requirement and also to have a proper near field radiation pattern with a high coupling coefficient, the use of a quarter-wave phase shifted grating etched into the active region (gain-coupled) and with a duty cycle larger than 50% is preferred. Forthis laser, since the intrinsic cavity will lase at the longer wavelength side of the stop-band [D. M. Adams, I. Woods, J. K. White, R. Finally, and D. Goodchild, “Gain-coupled DFB lasers with truncated quantum well second-order gratings,” Electronic Letters, vol. 37, no. 25, pp. 1521-1522, December 2001] and also the coupling coefficient due to the radiation field enhances the gain-coupling coefficient, spatial hole burning in the corresponding quarter-wave phase shifted device is highly suppressed. This means that the discrete quarter-wave phase shift can be made a practical surface-emitting device, without requiring extreme measures such as complicated electrodes or degrading the optical spatial profile through distributing the phase shift over a larger area. This is certainly very much true of a gain-coupled device with higher than 50% duty cycle and, to a lesser but still useful degree, in an index-coupled device with a similar duty cycle.

Following the same line of reasoning we find that spatial hole burning is particularly intense in a quarter-wave phase shifted second-order DFB laser with a loss-coupled grating. In this case, it is because the duty cycle must be less than 50% in order to avoid high material gain requirement that would follow from the high cavity losses associated with a greater than 50% duty cycle. Then the spatial hole burning and the intrinsic cavity both favour the mode on the shorter wavelength side of the stop band, leading to enhanced rather than suppressed hole burning effects.

Linewidth Considerations

The extreme suppression of spatial hole burning effects through a combination of a second order gain-coupled grating with a duty cycle greater than 50% allows the coupling coefficient to be very high without being accompanied by the usual performance degradation. The increased coupling coefficient has other beneficial effects in addition to the concentration of the optical field. An increased index-coupling coefficient reduces the threshold of the laser, requiring less gain to drive the laser. Therefore, less spontaneous emission is coupled to the laser mode which is a means to reduce the linewidth. Linewidth reduction is instrumental in reducing chirp and lengthening the reach of the device when used a directly modulated transmission source for information. Finally, the mirror loss is smaller since the field intensity at the edges is low when the coupling coefficient is large. This results in the spontaneous emission coupled to the different longitudinal modes to become less correlated, giving rise to a further reduction in the linewidth of the laser [P. Szczepanski and A. Kujawski,“Non-orthogonality of the longitudinal eigenmodes of a distributed feedback laser,” Optics Communications, vol. 87 pp. 259-262, 1992].

Numerical Results

To support the above models, the effect of the in-phase or anti-phase grating on the spatial hole burning of a quarter-wave phase shifted laser is calculated using numerical examples.

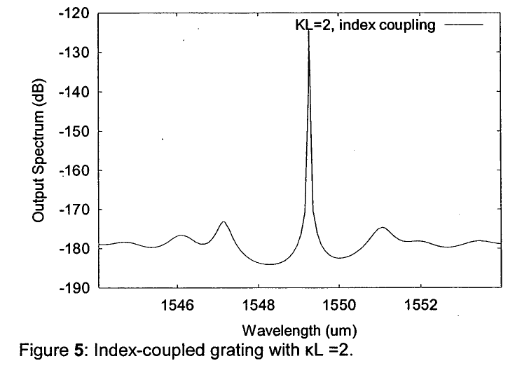

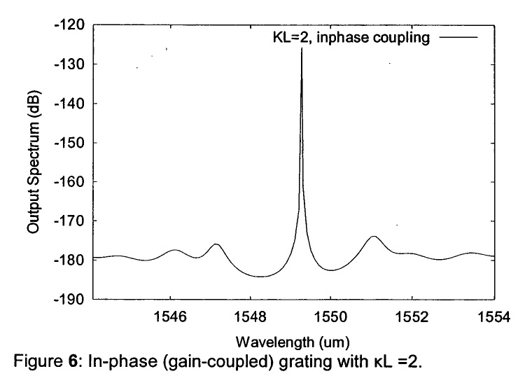

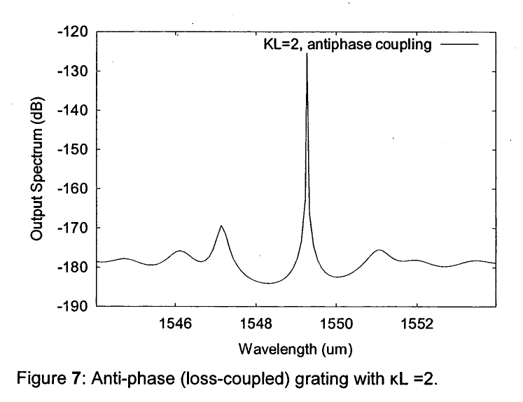

First, we consider an index-coupled, quarter-wave phase shifted DFB laser with a moderate normalized coupling coefficient of κL=2. Note here κ is the coupling coefficient due to refractive index modulation and L is the length of the laser cavity. Note that this coupling coefficient would be considered relatively high to the point of being potentially problematic for an edge-emitting device. This laser is well behaved even at a bias level of 100 mA as illustrated in FIG. 5. Introducing a 10% gain or loss coupling coefficient (in-phase and anti-phase respectively) still keeps the laser in the single mode regime as depicted in FIGS. 6 and 7, respectively. However, introducing a gain-coupling coefficient improves the spectral purity (FIG. 6) whereas introducing a loss coupling coefficient (FIG. 7) makes the laser more vulnerable to spatial hole burning. This is evident in the increased relative intensity of the shorter wavelength side mode.

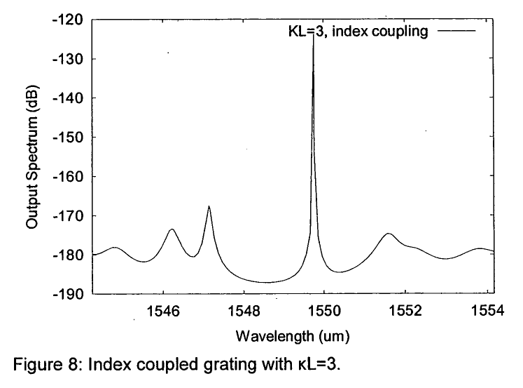

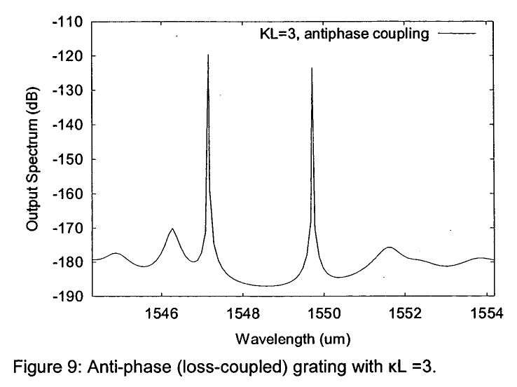

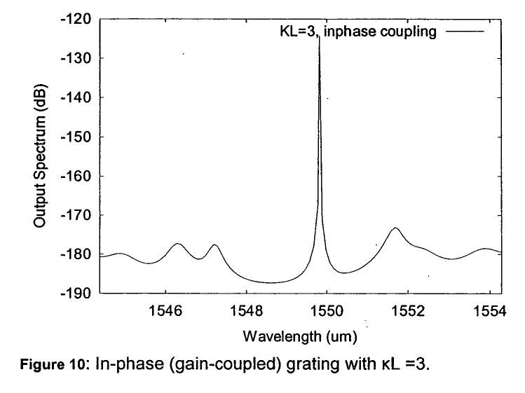

In the second example, we have increased the normalized coupling coefficient to κL=3. The bias current is again 100 mA. At this current injection level, the laser is single mode as shown in FIG. 8. However, it is interesting to note the significant side modes—particularly on the shorter wavelength side. By introducing 10% loss coupling (anti-phase grating) the laser runs into multimode operation as illustrated in FIG. 9. Thus spatial hole burning has caused badly degraded performance. On the other hand, introducing 10% gain coupling (in-phase grating) reduces the relative intensity of the mode at the shorter side of the stop band and hence the spatial hole burning effect is highly suppressed as illustrated in FIG. 10.

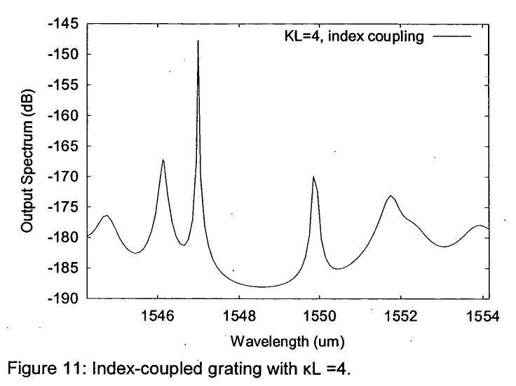

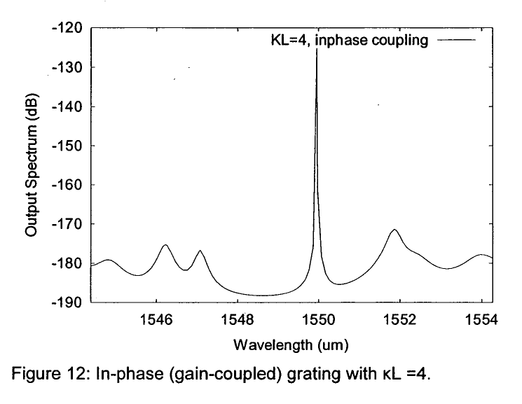

Finally, we consider a laser with a strong coupling coefficient of κL=4. As shown in FIG. 11, the index-coupled laser at 100 mA current injection runs into multimode operation. We have already shown that the loss-coupled case runs into trouble with κL=3 and so we do not consider it here. However, including 10% gain-coupling by using an in-phase gain grating, the laser operates in the single mode regime as illustrated in FIG. 12. Thus even very strongly coupled lasers, with the accompanying lower threshold currents, improved optical mode for fibre coupling, narrower linewidths and optimal surface emission efficiency, can operate without detriment from spatial hole burning for the preferred configuration of a second order gain-coupled grating with a discrete quarter-wave phase shift and greater than 50% duty cycle.

Experimental Results

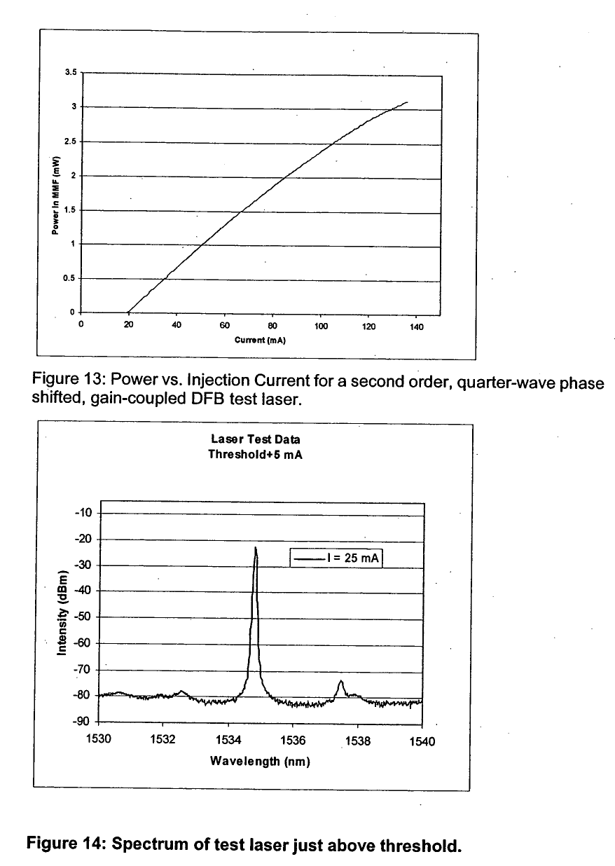

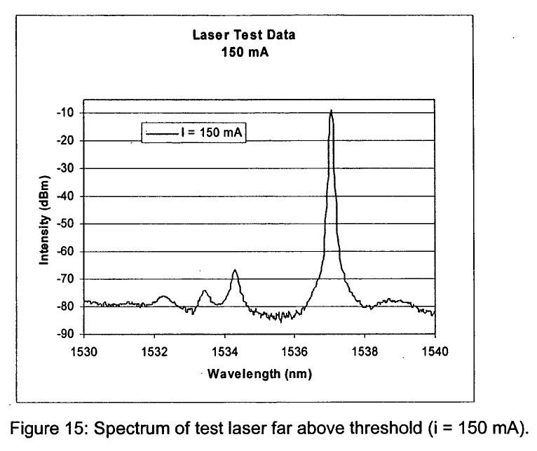

Suppression of spatial hole burning in a quarter-wave phase shifted DFB laser with second-order gain-coupled grating and duty cycle of 75% has been verified experimentally. In a typical device, having a duty cycle of 75%, the LI curve is plotted in FIG. 13 showing a threshold current of about 20 mA. The spectrum of the laser at a bias current of 25 mA is shown in FIG. 14. From the stop band, the normalized coupling coefficient for this device is κL>4. For such a high coupling coefficient, at bias levels not very far from the threshold current one would expect multi-mode operation for a typical DFB grating structure. However, as shown in FIG. 15, even at a bias level of 150 mA, which is more than 7 times the threshold current, the laser still remains single mode with side-mode suppression close to 60 dB. This clearly demonstrates the strong spatial hole burning suppression of the design.

Back-Reflection Insensitivity

Another important advantage of the second order surface emitting DFB laser design is that because of the nature of the coupling of the radiation out of the cavity, reflections within the optical path can not result in the creation of an external cavity, which would compete with and destabilize the internal cavity. The result is a laser much more robust to back-reflections than all traditional designs, including edge-emitting DFB, external cavity, and VCSEL lasers. This feature is particularly important in telecommunications applications over intermediate and longer distances (typically over 40 km) where optical isolators are routinely employed to prevent the performance degradation associated with back-reflected light.

Preferred Embodiments

The above design considerations can be implemented in numerous material systems. For telecommunications applications, the preferred material systems are InGaAsP/InP and AlInGaAs/InP since they are the current primary material systems for producing laser wavelengths in the range of 1.25 to 1.65 μm. However, newer material systems based on nitrides are under development and would also be suitable for telecommunications application.

The preferred embodiment employs an appropriate multi-quantum well structure of 5 to 10 quantum wells for providing gain in the desired wavelength band. The DFB grating is etched preferably using a dry-etch process to produce a square-shaped grating with a duty cycle (defined as the fractional length not etched in the grating formation) of greater than 50% and less than 90% and having an optimal range of 60-67%. This produces a balance between providing a strong coupling coefficient for high feedback and field concentration along with a high radiative coupling coefficient. Note that if the duty cycle drops to 50%, the radiative coupling is high but the coupling coefficient drops to 0. As the duty cycle increases, the coupling coefficient increases to a maximum at 75% duty cycle and then decreases to 0 at 100%, while the radiative coupling monotonically decreases to 0 at 100% duty cycle. Thus, as stated above, the optimum range is below 75% in the 64% range where the coupling is relatively strong for feedback and a localized optical mode while at the same time the radiative coupling has not decreased too strongly. The depth of the grating is chosen such that the normalized coupling coefficient κL is between 3 and 7, and is preferably between 4.5 and 5.5. These high values minimize power emission from the edge of the device, minimize linewidth, maximize FM response, and minimize chirp on direct modulation.

The grating also performs admirably though not as efficiently if it is wet-etched, which typically produces a triangular (or possibly trapezoidal) shaped grating. In this case the duty cycle (here defined as the fractional length not etched at the widest part of the grating) must be smaller, typically 40-60%, in order to optimize the relative coupling coefficients.

The device can be constructed using either a typical ridge waveguide (RWG) structure or a buried heterojunction (BH) structure. While the former is easier to fabricate, the junction is more difficult to thermally control, making performance in an uncooled application degraded. It is also worthy of note that for a RWG structure, the surface emission is best taken from the n-side, or substrate, of the device since opening a sufficiently long hole over the electrode injecting current into the ridge degrades the performance. In contrast, we have demonstrated that current injection can be well maintained even with openings as long as 250 μm in a BH structure, allowing light to be taken from the p-side top surface. From an optical perspective, both cases are easily workable.

For best thermal performance, a BH structure is preferred. Further, in fabricate the BH structure, it is preferred that the current blocking structure be formed using semi-insulating material rather than a reverse-biased p-n junction. The former case allows enhanced thermal management to be employed while reducing the parasitic capacitance that leads to degradation in high-speed applications.

A further advantage of the present invention can now be understood. The present invention comprehends a method of manufacturing where there is no need to cleave the individual elements from the wafer, nor is there any need to complete the end finishing or packaging of the laser structure before even beginning to test the laser structures for functionality. For example, referring to FIG. 1, the electrodes 12 and 14 are formed into the structure 10 as the structure is built and still in a wafer form. Each of the structures 10 can be electrically isolated from adjacent structures when on wafer, by appropriate patterning and deposition of electrodes on the wafer, leaving high resistance areas in the adjoining regions between gratings as noted above. Therefore, electrical properties of each of the structures can be tested on wafer, before any packaging steps occur, simply by injecting current into each grating structure on wafer. Thus, defective structures can be discarded or rejected before any packaging steps are taken (even before cleaving), meaning that the production of laser structures according to the present invention is much more efficient and thus less expensive than in the prior art where packaging is both more complex and required before any testing can occur. Thus cleaving, packaging and end finishing steps for non-functioning or merely malfunctioning laser structures required in the prior art edge emitting laser manufacture are eliminated by the present invention.

It will be appreciated by those skilled in the art that while reference has been made to preferred embodiments of the present invention various alterations and variations are possible without departing from the spirit of the broad claims attached. Some of these variations have been discussed above and others will be apparent to those skilled in the art. For example, while preferred structures are shown for the layers of the semiconductor laser structure of the invention other structures may also be used which yield acceptable results. Such structures may be either index coupled or gain coupled or both. What is believed important is to have an intrinsic cavity having a dominant mode on a longer wavelength side of the stop band.

We claim:

1. A surface emitting semiconductor laser comprising:
a semiconductor laser structure defining an intrinsic cavity having an active layer, opposed cladding layers contiguous to said active layer, a substrate and electrodes by which current can be injected into said semiconductor laser structure to cause said laser structure to emit an output signal in the form of at least a surface emission, said intrinsic cavity being configured to have a dominant mode on a longer wavelength side of a stop band;
a means for laterally confining the optical mode;
a second order distributed diffraction grating associated with said intrinsic cavity, said diffraction grating having a plurality of grating elements having periodically alternating optical properties when said current is injected into said laser structure said grating being sized and shaped to generate counter-running guided modes within the intrinsic cavity wherein said grating has a duty cycle of greater than 50% and less than 90%; and
a means for shifting a phase of said counter-running guided modes within the intrinsic cavity to alter a mode profile and radiative intensity of said output signal.

2. A surface emitting semiconductor laser as claimed in claim 1 wherein said alternating optical properties comprises alternating an index of refraction in conjunction with alternating a gain of the active layer.

3. A surface emitting semiconductor laser as claimed in claim 1 wherein said alternating optical properties comprises alternating an index of refraction.

4. A surface emitting semiconductor laser as claimed in claim 1 wherein said duty cycle is between 50% and 90%.

5. A surface emitting semiconductor laser according to claim 4 wherein said duty cycle is between 60 to 67%.

6. A surface emitting semiconductor laser as claimed in claim 1 wherein a center wavelength of said stop band lies in the range of 1.25 to 1.65 micrometers.

7. A surface emitting semiconductor laser according to claim 1 wherein said cavity includes a multi-quantum well structure of 5 to 10 quantum wells.

8. A surface emitting semiconductor laser according to claim 1 wherein said grating is a square shaped dry-etched grating.

9. A surface emitting semiconductor laser according to claim 1 wherein said grating has a depth such that the normalized coupling coefficient is between 3 and 7.

10. A surface emitting semiconductor laser according to claim 7 wherein said grating has a depth such that the normalized coupling coefficient is between 4.5 and 5.5.

11. A surface emitting semiconductor laser as claimed in claim 1 wherein said distributed diffraction grating is optically active and is formed in a gain medium in the active layer.

12. A surface emitting semiconductor laser as claimed in claim 1 wherein said structure further includes an adjoining region at least partially surrounding said grating in plan view.

13. A surface emitting semiconductor laser as claimed in claim 12 wherein said adjoining region further includes integrally formed absorbing regions located at either end of said distributed diffraction grating.

14. A surface emitting semiconductor laser as claimed in claim 12 further including an adjoining region having a photodetector.

15. A surface emitting semiconductor laser as claimed in claim 14 wherein said photodetector is integrally formed with said lasing structure.

16. A surface emitting semiconductor laser as claimed in claim 14 further including a feedback loop connected to said photodetector to compare a detected output signal with a desired output signal.

17. A surface emitting semiconductor laser as claimed in claim 16 further including an adjuster for adjusting an input current to maintain said output signal at a desired characteristic.

18. A surface emitting semiconductor laser as claimed in claim 12 wherein said adjoining region is formed from a material having a resistance sufficient to electrically isolate said grating, when said laser is in use.

19. A surface emitting laser as claimed in claim 1 wherein one of said electrodes includes a signal emitting opening.

20. A surface emitting laser as claimed in claim 1 wherein said means for laterally confining the optical mode is comprised of a ridge waveguide structure.

21. A surface emitting laser as claimed in claim 1 wherein said means for laterally confining the optical mode is comprised of a buried heterostructure configuration.

22. An array of surface emitting semiconductor lasers as claimed in claim 1 wherein said array includes two or more of said lasers on a common substrate.

23. An array of surface emitting semiconductor lasers as claimed in claim 22 wherein each of said two or more of said lasers produces an output signal having a different wavelength and output power and can be individually modulated.

24. An array of surface emitting semiconductor lasers as claimed in claim 22 wherein each of said two or more of said lasers produces an output signal having the same wavelength.

25. A method of fabricating surface emitting semiconductor lasers, said method comprising the steps of:
forming a plurality of semiconductor laser structures, defining a plurality of intrinsic laser cavities by forming, in successive layers on a common wafer substrate;
a first cladding layer, an active layer and a second cladding layer on said wafer substrate;
forming a plurality of second order distributed diffraction gratings to define said intrinsic cavities, wherein said intrinsic cavities have a dominant mode on the longer wavelength side of the stop band;
forming a phase shifter in said grating to alter a mode profile of an output signal from said semiconductor laser, said grating having a duty cycle of greater than 50% but less than 90%;
forming a means of laterally confining the optical mode; and
forming electrodes on each of said semiconductor laser structures on said wafer substrate for injecting current into each of said laser structures.

26. A method of fabricating surface emitting semiconductor lasers as claimed in claim 25 further comprising the step of simultaneously forming adjoining regions between said plurality of distributed diffraction gratings associated with said intrinsic cavities.

27. A method of fabricating surface emitting semiconductor lasers as claimed in claim 25 where said means of laterally confining the optical mode is a buried heterostructure configuration.

28. A method of fabricating surface emitting semiconductor lasers as claimed in claim 25 where said means of laterally confining the optical mode is a ridge waveguide structure.

29. A method of fabricating surface emitting semiconductor lasers as claimed in claim 25 further including the step of forming at either end of each of said gratings an absorbing region in said adjoining region.

30. A method of fabricating surface emitting semiconductor lasers as claimed in claim 25 further including the step of cleaving said wafer along said adjoining regions to form an array of lasers.
